(19) United States
(12) Patent Application Publication
(10) Pub. No.: US 2011/0018576 A1
(43) Pub. Date: Jan. 27, 2011

(54) METHOD AND DEVICE FOR TESTING SEMICONDUCTOR

(75) Inventor: Yoshiaki MAKINO, Ohtsu-shi (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/818,857

(22) Filed: Jun. 18, 2010

(30) Foreign Application Priority Data
Jul. 22, 2009 (JP) 2009-170856

(51) Int. Cl. G01R 31/26; G01R 31/02

(52) U.S. Cl. 324/762.05

(57) ABSTRACT

A semiconductor testing device of the prevent invention includes a current detecting circuit, an electric current drawing circuit, and a determining device. The electric current drawing circuit is connected to a semiconductor device under test, and draws a branched electric current branched from a measured electric current output from a second terminal based on predetermined electric voltage. The current detecting circuit is connected to the semiconductor device, and detects a detection current obtained by subtracting the branched electric current from the measured electric current. The determining device determines a quality of the semiconductor device based on the detection current.

### INCORPORATION BY REFERENCE

This application is based upon and claims the benefit of priority from Japanese patent application No. 2009-170856, filed on Jul. 22, 2009, the disclosure of which is incorporated herein in its entirety by reference.

### BACKGROUND

1. Field of the Invention

The present invention relates to a method and a device for testing a semiconductor, and in particular, to a method and a device for measuring an electric current through the semiconductor.

2. Description of Related Art

Tests of electric characteristics of a semiconductor device include tests for determining a quality of electric characteristics by measuring minute electric current flowing in the semiconductor device. The tests for measuring minute electric current is generally performed using a circuit as shown in FIG. 6.

In a minute electric current testing device as shown in FIG. 6, a constant voltage circuit 14 and a current detecting circuit 11 are connected to a semiconductor device 10 under test. Electric voltage V is applied to the semiconductor device 10 by the constant voltage circuit 14, thereby electric current I flows through the semiconductor device 10. Then, the current detecting circuit 11 detects the electric current I, and converts the electric current I into electric voltage. The electric voltage is converted into a digital signal by an A/D converter 15. After that, a determining device 13 determines the quality of the semiconductor device 10 based on the digital signal.

At this time, a transient phenomenon is caused by electric capacitances in a circuit of the minute electric current testing device and the semiconductor device 10. It takes a certain time for a transient electric current to stabilize so as to be able to be measured because the transient electric current begins to flow at the start of the test and decays with time.

Meanwhile, in Japanese Unexamined Patent Application Publication No. 10-253701, a semiconductor testing device as FIG. 7 is disclosed. To shorten the time by the transient electric current decays and stabilizes, the semiconductor testing device has a dummy capacitor 72 that has the same electric capacity as a bypass capacitor 71. The semiconductor testing device disclosed in Japanese Unexamined Patent Application Publication No. 10-253701 measures electric current flowing through the dummy capacitor 72 under the same conditions as in the bypass capacitor 71. Then, the semiconductor testing device shortens damping time of the transient electric current by subtracting the electric current flowing through the dummy capacitor 72 from all electric currents flowing through the IC (Integrated Circuit) and the bypass capacitor 71.

### SUMMARY

The semiconductor testing device disclosed in Japanese Unexamined Patent Application Publication No. 10-253701 is only used for testing power supply current. The semiconductor testing device is only used for a specific semiconductor device that has the bypass capacitor 71; the semiconductor testing device is not effective for other semiconductor devices. In addition, the semiconductor testing device can deal with the transient electric current caused by the bypass capacitor 71, but the semiconductor testing device cannot deal with the transient electric current caused by capacitors included in the semiconductor device 10.

Unfortunately, it takes long time for tests in semiconductors that cannot use techniques disclosed in Patent Application Publication No. 10-253701 shown in FIG. 7. This is because the measurement is started only after the transient electric current stabilizes.

A first exemplary aspect of the prevent invention is a semiconductor testing device for testing by applying predetermined electric voltage between a first terminal and a second terminal of a semiconductor device under test, including: an electric current drawing circuit connected to the second terminal, the electric current drawing circuit drawing a branched electric current branched from measured electric current output from the second terminal based on the predetermined electric voltage; a current detecting circuit connected to the second terminal, the current detecting circuit detecting detection current obtained by subtracting the branched electric current from the measured electric current; and a determining device determining a quality of the semiconductor device based on the detection current.

A second exemplary aspect of the prevent invention is a method for testing a semiconductor, including: applying a predetermined electric voltage between a first terminal and a second terminal of a semiconductor device under test; detecting detection current produced by subtracting branched electric current branched from measured electric current output from the second terminal based on the predetermined electric voltage; and determining a quality of the semiconductor device based on the detection current.

According to the exemplary aspects of the present invention, the transient electric current can flow fast, and test time can be shortened.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing an electric current testing device in accordance with a first exemplary embodiment of present invention;

FIG. 2 is a block diagram showing an electric current testing device in accordance with a second exemplary embodiment of present invention;

FIG. 3 is a circuit diagram showing an electric current testing device in accordance with a third exemplary embodiment of present invention;

FIG. 4 is a graph showing a time change of a transient electric current in accordance with the third exemplary embodiment of present invention;

FIG. 5 is a circuit diagram showing an electric current testing device in accordance with a fourth exemplary embodiment of present invention;

FIG. 6 is a block diagram showing a minute electric current testing device in accordance with a related art; and

FIG. 7 is a block diagram showing a power supply current testing device in accordance with a related art.

### DETAILED DESCRIPTION OF THE EXEMPLARY EMBODIMENTS

### First Exemplary Embodiment

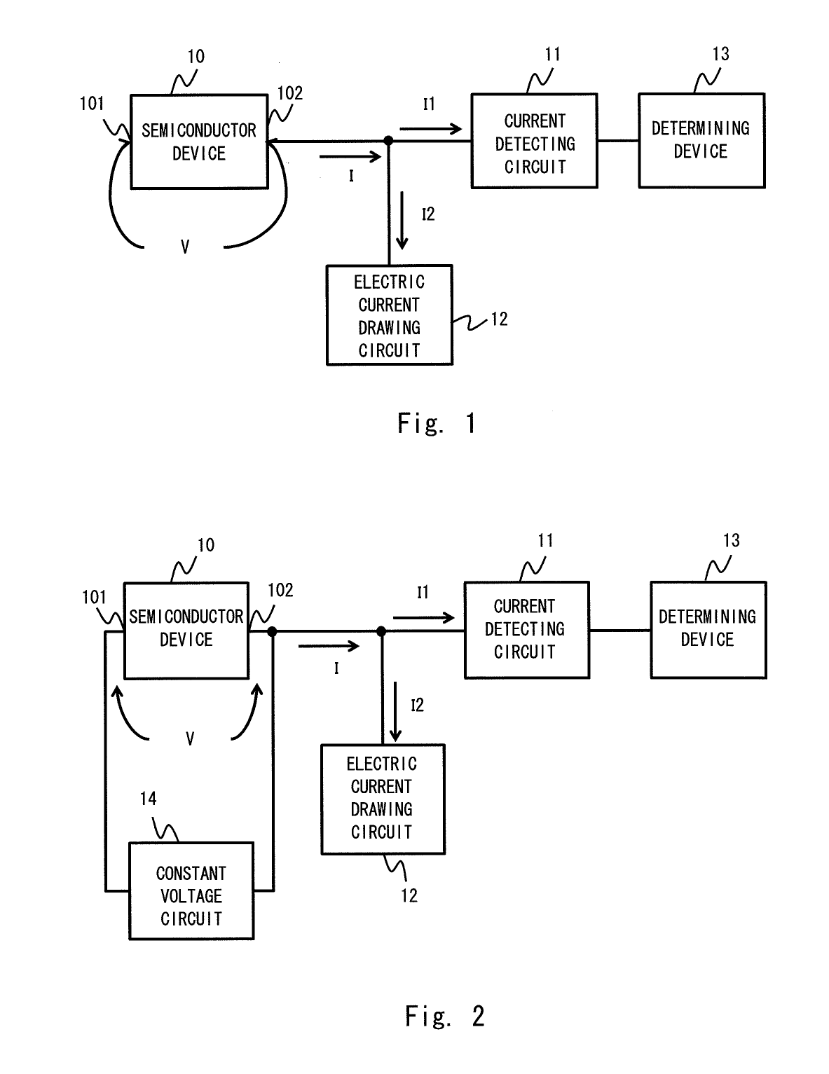

A first exemplary embodiment of the present invention will be described with reference to FIG. 1 in the following. FIG. 1 is a block diagram showing a semiconductor testing device in accordance with the first exemplary embodiment. A semiconductor testing device 1 includes a current detecting circuit 11, an electric current drawing circuit 12, and a determining device 13.

The current detecting circuit 11 is connected to a second terminal 102 of a semiconductor device 10 under test, and detects a detection current flowing through the current detecting circuit 11. The electric current drawing circuit 12 is connected to the second terminal 102, and draws a predetermined electric current. The determining device 13 is connected to the current detecting circuit 11, and determines the quality the quality of the semiconductor device 10 based on the detection current.

Next, operations of the semiconductor testing device 1 will be described. Firstly, a predetermined electric voltage V is applied between a first terminal 101 and the second terminal 102 of the semiconductor device 10. This will allow a measured electric current I to flow through the semiconductor device 10. Here, the electric voltage V is determined by a measured electric current necessary for testing the semiconductor device 10. In short, the electric voltage V is determined arbitrarily by product specs of the semiconductor device 10. The electric current I flows from the first terminal 101 to the second terminal 102. Then, the electric current I is output from the second terminal 102, and flows to the current detecting circuit 11 and the electric current drawing circuit 12.

The electric current drawing circuit 12 draws electric current I2 into the electric current drawing circuit 12 from the electric current I flowing from the semiconductor device 10. The electric current I2 that branches from the electric current I and is drawn to the electric current drawing circuit 12 is called a branched electric current. Then, electric current I1 produced by subtracting the electric current I2 from the electric current I output from the semiconductor device 10 flows to the current detecting circuit 11 as the detection current.

The current detecting circuit 11 detects the electric current I1. Then, the determining device 13 determines the quality of the semiconductor device 10 based on the electric current I1 after a transient phenomenon of the electric current I1 decays and reaches a state of equilibrium. Specifically, the current detecting circuit 11 determines the quality based on a sum of the electric current I1 and the electric current I2. Note that the semiconductor device 10 can also be a transistor, a diode, etc. or an integrated circuit including transistors and diodes.

As described above, using the semiconductor testing device 1 in this exemplary embodiment of the present invention, the electric current drawing circuit 12 draws the branched electric current immediately after the electric voltage V is applied. Accordingly, a transient electric current can promptly reach a state of equilibrium and test time can be shortened.

### Second Exemplary Embodiment

A second exemplary embodiment of the present invention will be described with reference to FIG. 2. FIG. 2 is a block diagram showing a semiconductor testing device of the second exemplary embodiment. The semiconductor testing device 2 in FIG. 2 includes a constant voltage circuit 14 in addition to the components of the semiconductor testing device 1 described in the first exemplary embodiment.

The second terminal 102 of the semiconductor device 10 is connected to the current detecting circuit 11 and the electric current drawing circuit 12 as is similar to the first exemplary embodiment. The constant voltage circuit 14 is connected to the semiconductor device 10, and applies the predetermined electric voltage V between the first terminal 101 and the second terminal 102. Therefore, the electric current I flows through the semiconductor device 10.

As described above, the semiconductor testing device 2 in this exemplary embodiment includes the constant voltage circuit 14. Hence, the semiconductor testing device 2 can measure not only the power supply current of the semiconductor device 10 under test but also the minute electric current produced by the predetermined electric voltage V applied by the constant voltage circuit 14.

### Third Exemplary Embodiment

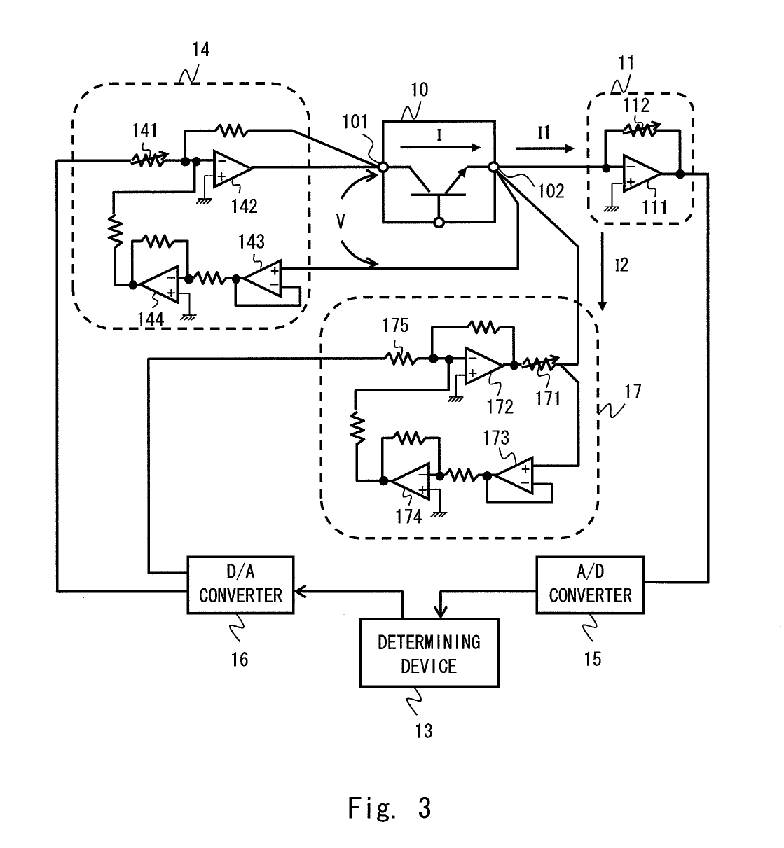

A third exemplary embodiment of the present invention will be described with reference to FIG. 3. FIG. 3 is a specific circuit diagram of the block diagram shown in FIG. 2. FIG. 3 shows a semiconductor testing device 3. The semiconductor testing device 3 in FIG. 3 includes an A/D converter 15 and a D/A converter 16, in addition to the components of the semiconductor testing device 2 described in the second exemplary embodiment. The semiconductor testing device 3 includes a constant electric current circuit 17 as the electric current drawing circuit 12. In FIG. 3, one terminal of the current detecting circuit 11 is connected to the second terminal 102. Another terminal of the current detecting circuit 11 is connected to the A/D converter 15. One terminal of the constant electric current circuit 17 is connected to the second terminal 102. Another terminal of the constant electric current circuit 17 is connected to the D/A converter 16. Further, an input terminal of the A/D converter 15 is connected to the current detecting circuit 11, and an output terminal of the A/D converter 15 is connected to the determining device 13. An input terminal of the D/A converter 16 is connected to the determining device 13, and an output terminal of the D/A converter 16 is connected to the constant voltage circuit 14 and the constant electric current circuit 17.

The current detecting circuit 11 includes an operational amplifier (OP-Amp) 111 and a current sensing resistor 112. The current sensing resistor 112 is connected to the second terminal 102. The electric current I1 flows through the current sensing resistor 112. The OP-Amp 111 converts electric current I1 flowing through the current sensing resistor 112 to electric voltage.

The constant voltage circuit 14 includes a variable resistor 141, OP-Amps 142, 143, and 144. The variable resistor 141 is connected to the OP-Amp 142, and multiplies output electric voltage from the D/A converter 16 by several times to flow electric current I sufficient for measuring the measured electric current. For example, if the output electric voltage of the D/A converter 16 is regulated under 10 V and the electric voltage V that should be tested is 50 V, the output electric voltage of the D/A converter 16 is set to 0.5 V or 5 V and the constant voltage circuit 14 multiplies the output electric voltage by 10 times or 100 times. Therefore the constant voltage circuit 14 can apply 50 V to the semiconductor device 10 as a desired electric voltage. The OP-Amp 142 applies the multiplied electric voltage to the first terminal 101. The OP-Amp 143 is connected to the second terminal 102, and is a buffer amplifier for preventing the electric current I from being mixed into the constant voltage circuit 14 with extremely high impedance. The OP-Amp 144 is connected to an input terminal of the OP-Amp 142. The OP-Amp 144 feeds back electric voltage at the second terminal 102 to the OP-Amp 142 so that the electric voltage V as the predetermined electric voltage is applied and kept.

Further, the constant electric current circuit 17 includes a variable resistor 171, OP-Amps 172, 173, 174, and a resistor 175. One terminal of the variable resistor 171 is connected to the second terminal 102. Another terminal of the variable resistor 171 is connected to the OP-Amp 172. In the constant electric current circuit 17, electric voltage between both terminals of the variable resistor 171 is determined based on electric voltage applied the resistor 175, a value of the variable resistor 171, and electric voltage at the second terminal 102. The electric current I2 flows through the variable resistor 171 as desired current by the electric voltage between both terminals of the variable resistor 171. The OP-Amp 173 prevents the electric current I2 from being mixed into the constant electric current circuit 17 as is similar to the OP-Amp 143 described above.

The electric voltage between both terminals of the variable resistor 171 should be stationary to flow constant electric current to the variable resistor 171. Therefore, the OP-Amp 174 feeds back electric voltage of the variable resistor 171 to the OP-Amp 172 to make the electric voltage between both terminals of the variable resistor 171 stationary as is similar to the OP-Amp 144. The electric current I2 is drawn to a ground of the OP-Amp 172.

Next, operations of the semiconductor testing device 3 shown in FIG. 3 will be described. First, the determining device 13 outputs electric voltage to apply the electric voltage V to the semiconductor device 10 and flow the electric current I2 that branches from the electric current I as a digital signal. The D/A converter 16 converts the digital signal from the determining device 13 to an analog voltage, and applies the analog voltage to the constant voltage circuit 14 and the constant electric current circuit 17.

Then, the constant voltage circuit 14 multiplies the analog voltage from the D/A converter 16 several times and applies the electric voltage V to the semiconductor device 10. The desired electric current I flows through the semiconductor device 10 by applying the electric voltage V. Note that FIG. 3 shows measurement of the electric current between a collector and an emitter of the semiconductor device 10 as the first terminal 101 and the second terminal 102. However, electric current can be measured between arbitrary terminals of the base, the emitter, and the collector of the semiconductor device 10 for two terminals to which the electric voltage V to flow the electric current I is applied.

The electric current I2 divided from the electric current I is drawn to the constant electric current circuit 17, another electric current I1 divided from the electric current I flows to the current detecting circuit 11. Then, the electric voltage applied to the constant electric current circuit 17 is determined based on a prediction of an amount of the electric current I2. The prediction of the amount of the electric current I2 is determined based on a designed value of the semiconductor device 10 and a typical value of it under the same conditions as the designed value.

The current detecting circuit 11 detects the electric current I1 supplied from the semiconductor device 10, and converts the electric current I1 to the analog voltage. The A/D converter 15 converts the analog voltage to the digital signal and sends the digital signal to the determining device 13. Further, the determining device 13 calculates the electric current I1 by the digital signal sent from the A/D convertor 15. The determining device 13 calculates the electric current I flowing through the semiconductor device 10 based on a sum of the electric current I1 and the electric current I2 determined by the value of the variable resistor 171. Thus, the determining device 13 determines the quality of the tested semiconductor device 10.

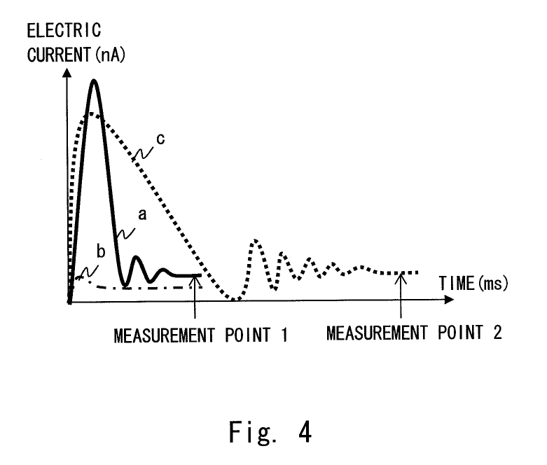

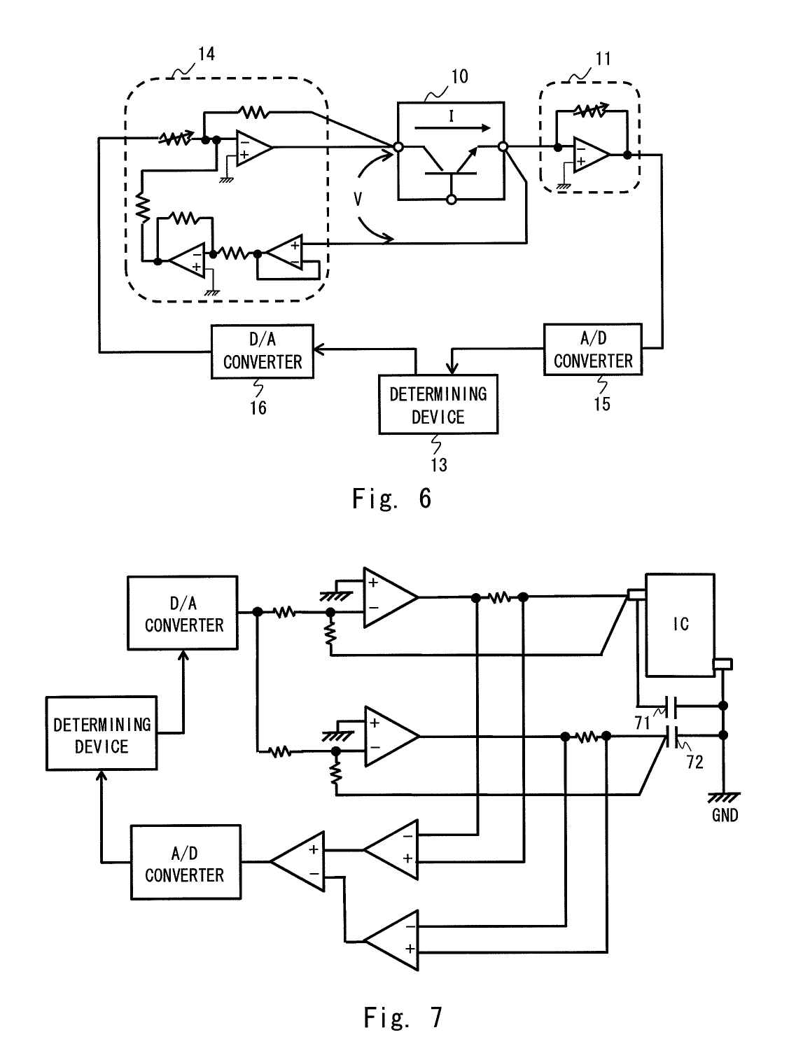

Next, a time change of the transient electric current using the semiconductor testing device 3 of the third exemplary embodiment and the one using the semiconductor testing device of the related art shown in FIG. 6 will be described with FIG. 4. The waveforms in FIG. 4 each shows the time change of the transient electric current. A vertical axis shows an electric current and a horizontal axis shows time. In FIG. 4, a waveform with solid line a shows the electric current I (the electric current I1+the electric current I2) measured in the test using the semiconductor testing device 3 of this exemplary embodiment. Further, a waveform with chain line b shows the electric current I2 that is branched from the electric current I and is drawn by the constant electric current circuit 17. Furthermore, a waveform with dotted line c shows the measured electric current I using the semiconductor testing device in FIG. 6.

In FIG. 4, each point that transient electric currents shown with the solid line a and dotted line c decay and reach a state of equilibrium so as to be able to measure the currents are shown with measurement point 1 and measurement point 2. In the semiconductor testing device 3 shown in FIG. 3, much electric current flows shortly after the test starts than an amount of electric current by the related art shown with dotted line c. This is because the constant electric current circuit 17 draws electric current I2 branched from the electric current I in addition to the electric current I1 flowing to the current detecting circuit 11. As a result, capacitors included in the semiconductor device 10 and other circuits are quickly charged. Thus, less time is needed for decaying the electric current I. Therefore, the measurement point 1 using the semiconductor testing device 3 of the present invention occurs earlier than the measurement point 2 using the related art.

As described above, the semiconductor testing device 3 of this exemplary embodiment can branch the constant electric current I2 from the measured electric current I and draw the constant electric current I2. Accordingly, branched electric current do not affect detecting the electric current I1. Therefore, it is easy to determine whether the electric current I1 reaches a state of equilibrium.

### Fourth Exemplary Embodiment

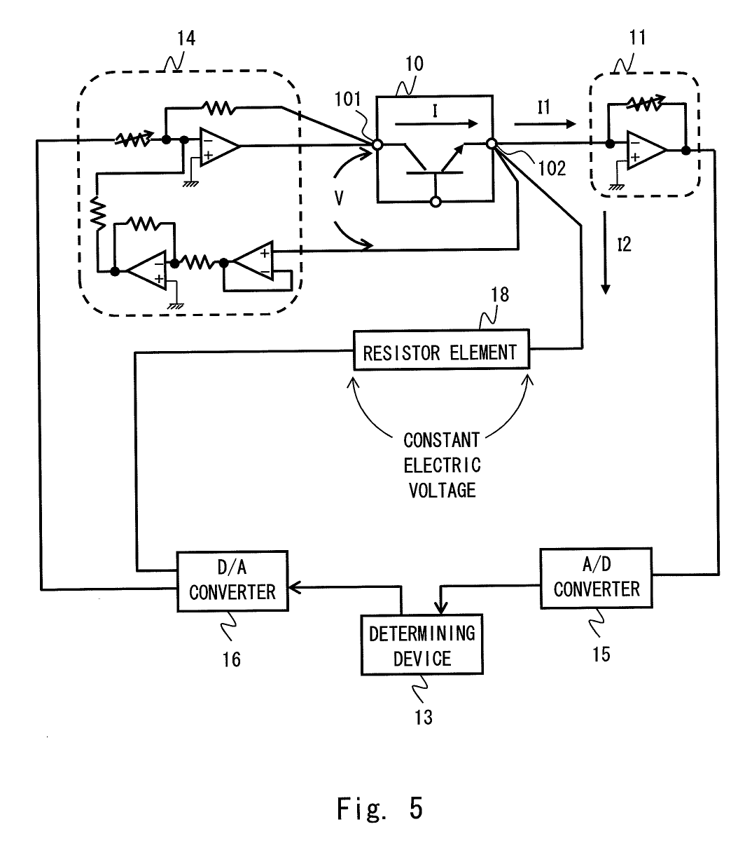

FIG. 5 is a block diagram showing a semiconductor testing device 4 of the fourth exemplary embodiment. In the semiconductor testing device 4 in FIG. 5, the constant electric current circuit 17 of the semiconductor testing device 3 in FIG. 3 is replaced with a resistor element 18. The resistor element 18 includes both terminals to which constant electric voltage is applied. Other components are the same as the semiconductor testing device 3 shown in FIG. 3, so these explanations are omitted.

The resistor element 18 is connected to the second terminal 102, and constant electric voltage is applied to both terminals. Therefore, the resistor element 18 can flow constant electric current. Further, an amount of the branched electric current I2 can be determined by changing a resistor value of the resistor element 18 or the constant electric voltage.

Using the semiconductor testing device 4 of this exemplary embodiment, the constant electric current I2 can be branched from the measured electric current I and drawn to the resistor element 18 without using a complex constant electric current circuit including OP-Amps and other elements.

From first to fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor testing device for testing by applying predetermined electric voltage between a first terminal and a second terminal of a semiconductor device under test, comprising:
an electric current drawing circuit that connects to the second terminal, the electric current drawing circuit drawing a branched electric current branched from measured electric current output from the second terminal based on the predetermined electric voltage;
a current detecting circuit that connects to the second terminal, the current detecting circuit detecting a detection current obtained by subtracting the branched electric current from the measured electric current; and
a determining device that determines a quality of the semiconductor device based on the detection current.

2. The semiconductor testing device according to claim 1, wherein
the current detecting circuit converts the detection current to electric voltage, and
the determining device determines the quality of the semiconductor device based on a sum of the detection current depending on the electric voltage converted by the current detecting circuit and the branched electric current.

3. The semiconductor testing device according to claim 1, further comprising a constant voltage circuit that applies the predetermined electric voltage between the first terminal and the second terminal of the semiconductor device.

4. The semiconductor testing device according to claim 1, wherein the branched electric current is a constant electric current.

5. A method for testing a semiconductor, comprising:
applying a predetermined electric voltage between a first terminal and a second terminal of a semiconductor device under test;
detecting detection current produced by subtracting branched electric current, branched from measured electric current output from the second terminal based on predetermined electric voltage; and
determining a quality of the semiconductor device based on the detection current.

6. The method for testing the semiconductor according to claim 5, further comprising converting the detection current to electric voltage;
wherein the quality of the semiconductor device is determined based on a sum of the detection current depending on the converted electric voltage and the branched electric current.

7. The method for testing the semiconductor according to claim 5, wherein the branched electric current is constant electric current.
